(19) United States
(12) Patent Application Publication
(10) Pub. No.: US 2022/0278681 A1
(43) Pub. Date: Sep. 1, 2022

(54) SWITCH DRIVING CIRCUIT

(71) Applicant: ROHM CO., LTD., Kyoto-shi, Kyoto (JP)

(72) Inventors: Shinya TAJIMA, Kyoto (JP); Seiya KITAGAWA, Kyoto (JP)

(21) Appl. No.: 17/630,789

(22) PCT Filed: Jul. 1, 2020
(86) PCT No.: PCT/JP2020/025755

§ 371 Date: Jan. 27, 2022

(30) Foreign Application Priority Data
Sep. 2, 2019 (JP) 2019-159866

(51) Int. Cl. H03K 17/567; H03K 17/16

(52) U.S. Cl. CPC H03K 17/567; H03K 17/161

(57) ABSTRACT

For example, a switch driving circuit 1 includes a signal source SG that pulse-drives a gate signal G for a switching element SW (e.g., IGBT) connected in series with a load RL (e.g., resistive load), a gate resistor Rg connected between the signal source SG and the switching element SW, a gate capacitor Cge of which the first terminal is connected to the gate of the switching element SW, a dumping resistor Rd connected between the second terminal of the gate capacitor Cge and the emitter of the switching element SW. The resistance value of the dumping resistor Rd can be set to be equal to, for example, 1/100 to 1/1000 of the resistance value of the gate resistor Rg. For example, the turning-on transition period τon and the turning-off transition period τoff of the switching element SW can each be 80 μs to 1 s (about 120 μs).

### TECHNICAL FIELD

The invention disclosed herein relates to a switch driving circuit.

### BACKGROUND ART

Conventionally, various types of switch driving circuits have been devised which turn on and off a switching element.

An example of known technology related to what has just been mentioned is seen in Patent Document 1 identified below.

### LIST OF CITATIONS

### Patent Literature

Patent Document 1: Japanese Patent Application published as No. 2015-37256.

### SUMMARY OF THE INVENTION

### Problem to be Solved by the Invention

Inconveniently, conventional switch driving circuits may cause gate oscillation during low-speed switching.

In view of the above-mentioned problem encountered by the present inventor, an object of the invention disclosed herein is to provide a switch driving circuit that can suppress gate oscillation during low-speed switching.

### Means for Solving the Problem

According to one aspect of what is disclosed herein, a switch driving circuit includes a signal source configured to pulse-drive a gate signal for a switching element connected in series with a load, a gate resistor connected between the signal source and the gate of the switching element, a gate capacitor of which the first terminal is connected to the gate of the switching element, and a dumping resistor connected between the second terminal of the gate capacitor and the emitter or source of the switching element (a first configuration).

In the switch driving circuit of the first configuration described above, the resistance value of the dumping resistor may be equal to 1/100 to 1/1000 of the resistance value of the gate resistor (a second configuration).

In the switch driving circuit of the first or second configuration described above, the turning-on transition period and the turning-off transition period of the switching element may be each 80 μs to 1 s (a third configuration).

According to another aspect of what is disclosed herein, a load device includes a load, a switching element connected in series with the load, and the switch driving circuit of any one of the first to third configurations described above (a fourth configuration).

In the load device of the fourth configuration described above, the switching element may be an IGBT (insulated-gate bipolar transistor), or may be an SiC-MOSFET (metal-oxide-semiconductor field-effect transistor) or an Si-MOSFET (a fifth configuration).

In the load device of the fourth or fifth configuration described above, the load may be a resistive load (a sixth configuration).

According to yet another aspect of what is disclosed herein, a vehicle includes a battery, and a load device of any one of the fourth to sixth configurations described above configured to be fed with electric power from the battery (a seventh configuration).

In the vehicle of the seventh configuration described above, the load device may be a heater (an eighth configuration).

The vehicle of the eighth configuration described above may be one that has no internal combustion engine to serve as a heat source (a ninth configuration).

In the vehicle of any one of the seventh to ninth configurations described above, the battery may be a driving battery configured to output a voltage of 100 to 800 V (a tenth configuration).

### Advantageous Effects of the Invention

According to the invention disclosed herein, it is possible to provide a switch driving circuit that can suppress gate oscillation during low-speed switching.

### BRIEF DESCRIPTION OF DRAWINGS

FIG. 1 is a diagram showing an overall configuration of a load device (a comparative example of a switch driving circuit);

FIG. 2 is a diagram showing the turn-on response of a switching element in the comparative example;

FIG. 3 is a diagram showing the turn-off response of the switching element in the comparative example;

FIG. 4 is a diagram showing a switch driving circuit according to a first embodiment;

FIG. 5 is a diagram showing the turn-on response of the switching element in the first embodiment;

FIG. 6 is a diagram showing the turn-off response of the switching element in the first embodiment;

FIG. 7 is a diagram showing a switch driving circuit according to a second embodiment;

FIG. 8 is a diagram showing the turn-on response of the switching element in the second embodiment;

FIG. 9 is a diagram showing the turn-off response of the switching element in the second embodiment; and

FIG. 10 is a diagram showing one configuration example of a vehicle.

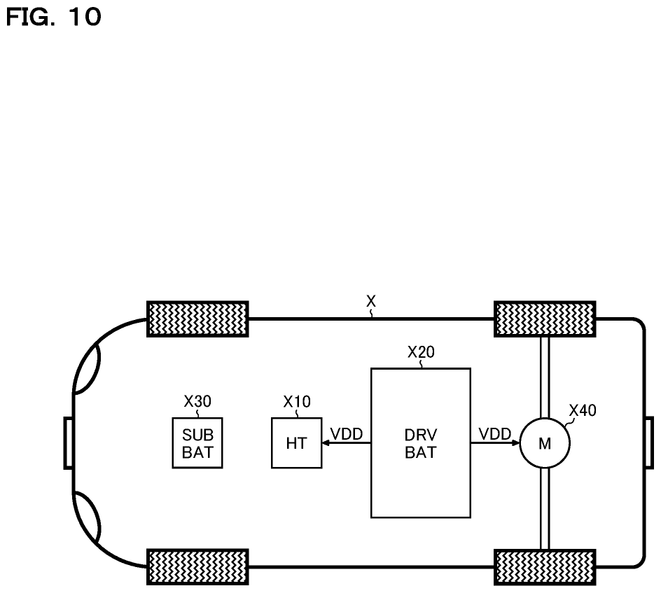

### DESCRIPTION OF EMBODIMENTS

<Load Device>

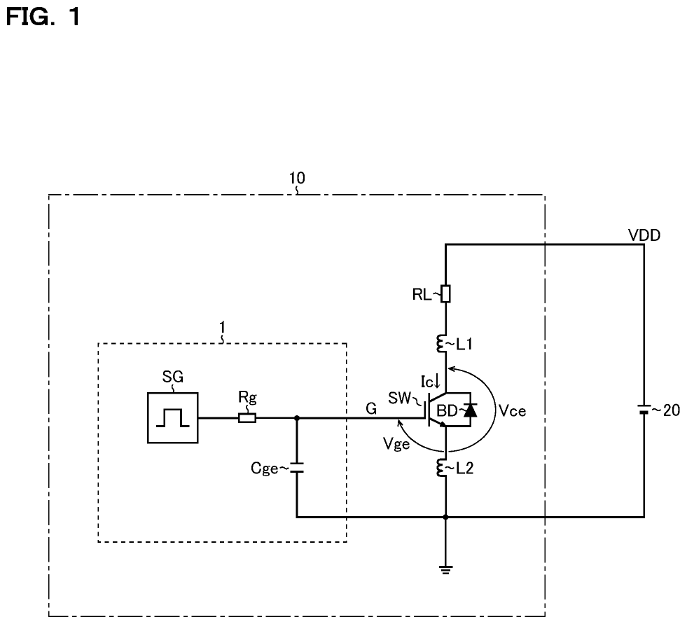

FIG. 1 is a diagram showing an overall configuration of a load device including a switch driving circuit. The load device 10 of this configuration example includes a switch driving circuit 1, a switching element SW (an IGBT in the diagram), and a load RL. The load device 10 operates by being fed with a supply voltage VDD from a power supply 20.

The load RL is a resistive load. The first terminal of the load RL is connected to a positive terminal (an application terminal for the supply voltage VDD).

The collector of the switching element SW is connected to the second terminal of the load RL. The emitter of the switching element SW is connected to a negative terminal of the power supply 20 (i.e., a grounded terminal). The gate of the switching element SW is connected to an output terminal of the switch driving circuit 1 (i.e., an application terminal for a gate signal G). The switching element SW is accompanied by conductor inductances L1 and L2 at its collector and emitter respectively. The switching element SW is also accompanied by a body diode BD between its collector and emitter, with these acting as the cathode and anode, respectively, of the body diode BD.

Thus connected in series between the second terminal of the load RL and the negative terminal of the power supply 20, the switching element SW is on when the gate signal G is at high level and is off when the gate signal G is at low level.

FIG. 1 shows an IGBT as an example of the switching element SW; instead, it is also possible to use, for example, an SiC-MOSFET or an Si-MOSFET. In that case, the collector and emitter mentioned above can be read as the drain and source.

<Switch Driving Circuit (Comparative Example)>

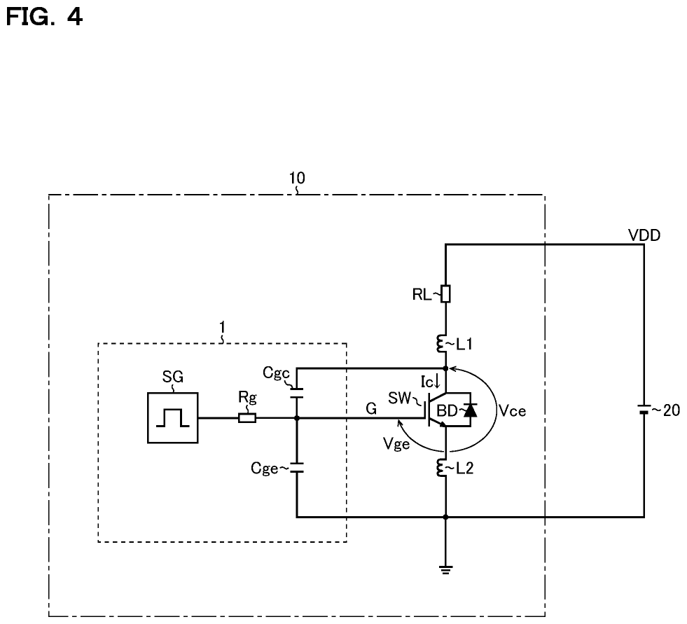

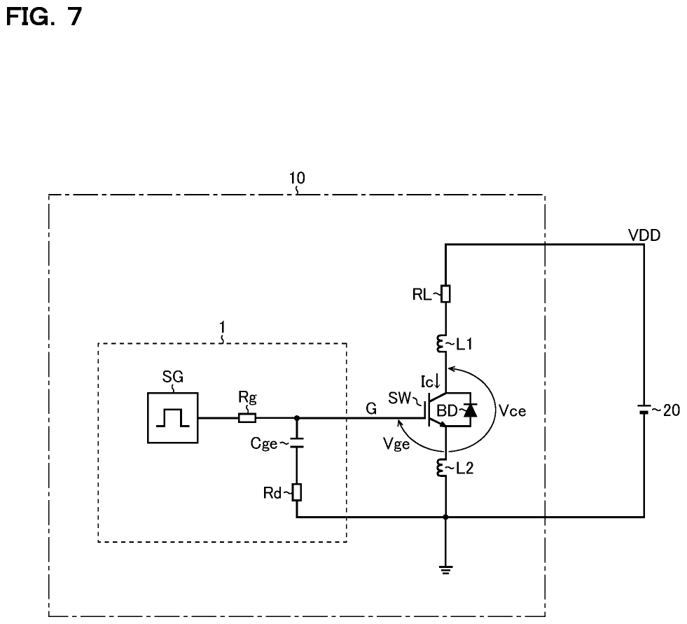

With reference still to FIG. 1, the switch driving circuit 1 will be described. The diagram shows a comparative example that is described first below, prior to a description of a novel embodiment (FIGS. 4 and 7) of the switch driving circuit 1, for comparison with it.

The switch driving circuit 1 of this comparative example plays the main role in turning the switching element SW on and off and includes a signal source SG, a gate resistor Rg, and a gate capacitor Cge.

The signal source SG pulse-drives the gate signal G for the switching element SW, for example, such that the collector current Ic that passes through the switching element SW equals a target value, or such that the amount of heat generated by the load RL (i.e., the sensing value of a temperature sensor) equals the target value.

The first terminal of the gate resistor Rg is connected to the output terminal for the signal source SG. The second terminal of the gate resistor Rg is connected to the gate of the switching element SW. The first terminal of the gate capacitor Cge is connected to the gate of the switching element SW. The second terminal of the gate capacitor Cge is connected to the emitter of the switching element SW.

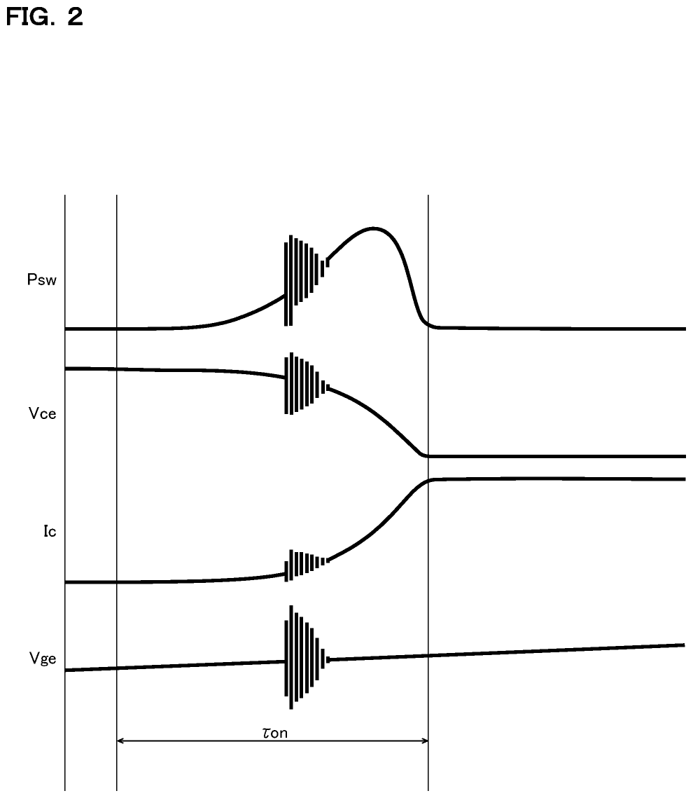

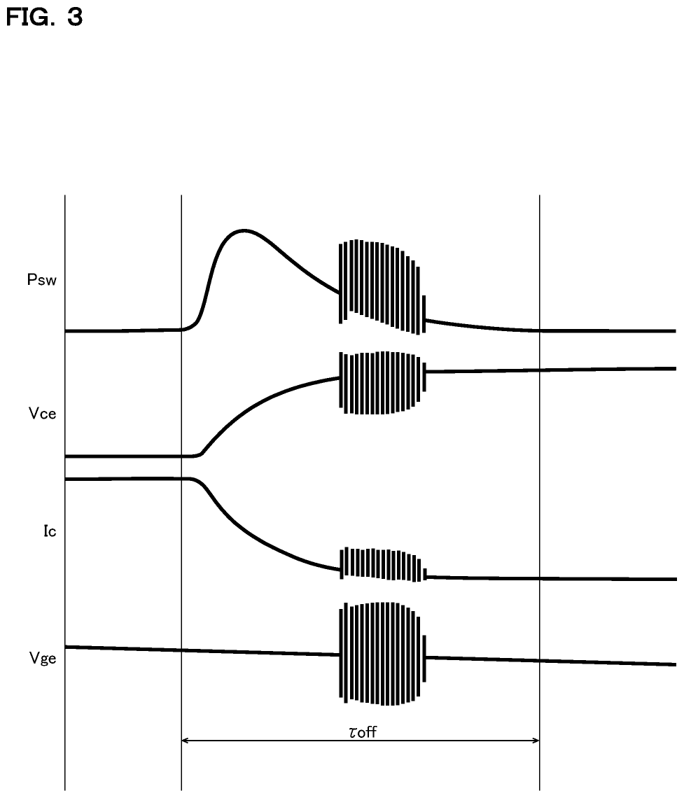

FIGS. 2 and 3 are diagrams showing the turn-on response and the turn-off response, respectively, of the switching element SW of the comparative example, illustrating with respect to the switching element SW, from top down, the switching loss Psw (=Ic×Vce), the collector-to-emitter voltage Vce, the collector current Ic, and the gate-to-emitter voltage Vge (i.e., the gate signal G).

As the gate-to-emitter voltage Vge increases while turning on the switching element SW, the collector-to-emitter voltage Vce decreases, and the collector current Ic increases (see FIG. 2). In contrast, as the gate-to-emitter voltage Vge decreases while turning off the switching element SW, the collector-to-emitter voltage Vce increases, and the collector current Ic increases (see FIG. 3).

Incidentally, to suppress switching noise that accompanies the turning on/off of the switching element SW, it is preferable that the switching element SW be turned on and off at a low speed (at a low slew rate).

For example, by setting the turning-on transition period τon (i.e., the time required from the start of turning-on to the completion of turning-on) and the turning-off transition period τoff (i.e., the time required from the start of turning-off to the completion of turning-off) each at 80 μs to 1 s (for example, 120 μs), it is possible to sufficiently suppress switching noise; this eliminates the need to introduce a noise filter in the switch driving circuit 1. It is thus possible to reduce the cost and size of the switch driving circuit 1 (and hence of the load device 10).

However, turning on and off the switching element SW at a low speed (at a low slew rate) may cause, as shown in FIGS. 2 and 3, gate oscillation during the turning-on transition period τon and the turning-off transition period τoff. In particular, in a load device 10 with a switching element SW that is accompanied by high conductor inductances L1 and L2 at its collector and emitter respectively, the just-mentioned gate oscillation is notable, possibly causing problems in the turning on/off of the switching element SW.

The following description discusses a novel embodiment of the switch driving circuit 1 that can suppress gate oscillation during low-speed switching.

<Switch Driving Circuit (First Embodiment)>

FIG. 4 is a diagram showing the switch driving circuit 1 according to a first embodiment. The switch driving circuit 1 according to the embodiment includes the circuit elements in FIG. 1 (the signal source SG, the gate resistor Rg, and the gate capacitor Cge), and in addition includes, as a means for suppressing gate oscillation during low-speed switching, a gate capacitor Cgc. The gate capacitor Cgc is connected between the gate and the collector of the switching element SW.

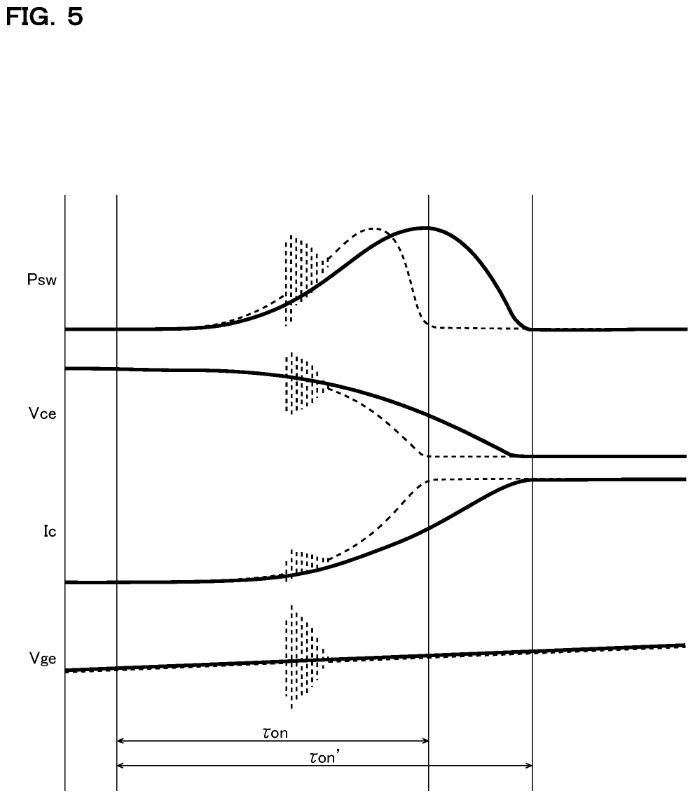

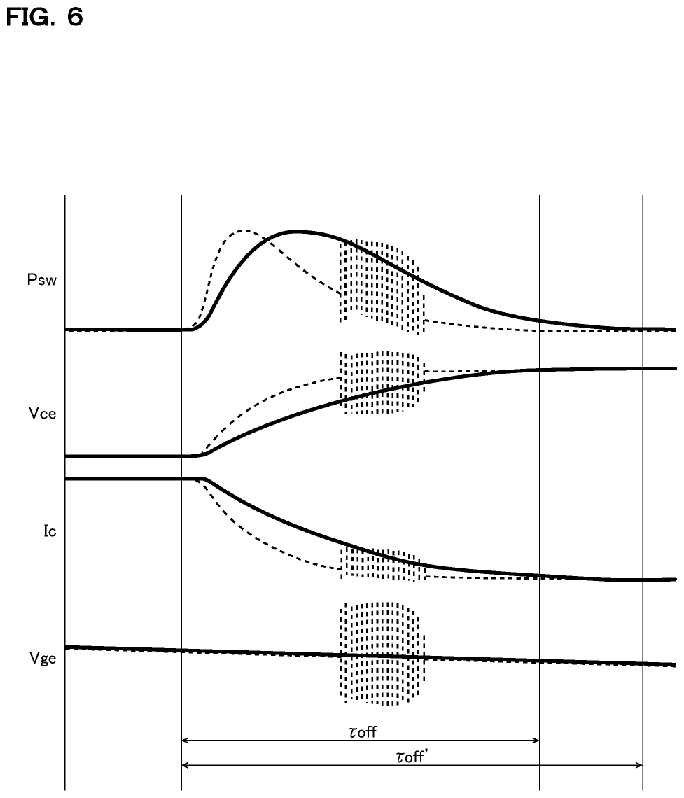

FIGS. 5 and 6 are diagrams showing the turn-on response and the turn-off response, respectively, of the switching element SW of the first embodiment (FIG. 4), illustrating with respect to the switching element SW, from top down, the switching loss Psw, the collector-to-emitter voltage Vce, the collector current Ic, and the gate-to-emitter voltage Vge. The short-stroke broken lines in the diagrams show the turn-on response and the turn-off response of the switching element SW of the comparative example (FIG. 1) described previously.

With the switch driving circuit 1 of the embodiment, by adjusting as necessary the resistance value of the gate resistor Rg and the capacitance values of the gate capacitor Cge and Cgc, it is possible to suppress the gate oscillation described above.

However, as a trade-off, the turning-on transition period τon′ and the turning-off transition period τoff of the switching element SW are longer than the turning-on transition period τon and the turning-off transition period τoff of the comparative example. In particular, if the turning-on transition period τon and the turning-off transition period τoff are set at large values (for example, several hundred microseconds to one second) in the first place, τon′ and τoff can be extremely large, possibly leading to a very large switching loss Psw.

<Switch Driving Circuit (Second Embodiment)>

FIG. 7 is a diagram showing the switch driving circuit 1 according to a second embodiment. The switch driving circuit 1 according to the embodiment includes the circuit elements in FIG. 1 (the signal source SG, the gate resistor Rg, and the gate capacitor Cge), and in addition includes, as a means for suppressing gate oscillation during low-speed switching, a dumping resistor Rd.

The dumping resistor Rd is connected between the second terminal of the gate capacitor Cge and the emitter of the switching element SW. The resistance value of the dumping resistor Rd can be set to be equal to, for example, 1/100 to 1/1000 of the resistance value of the gate resistor Rg.

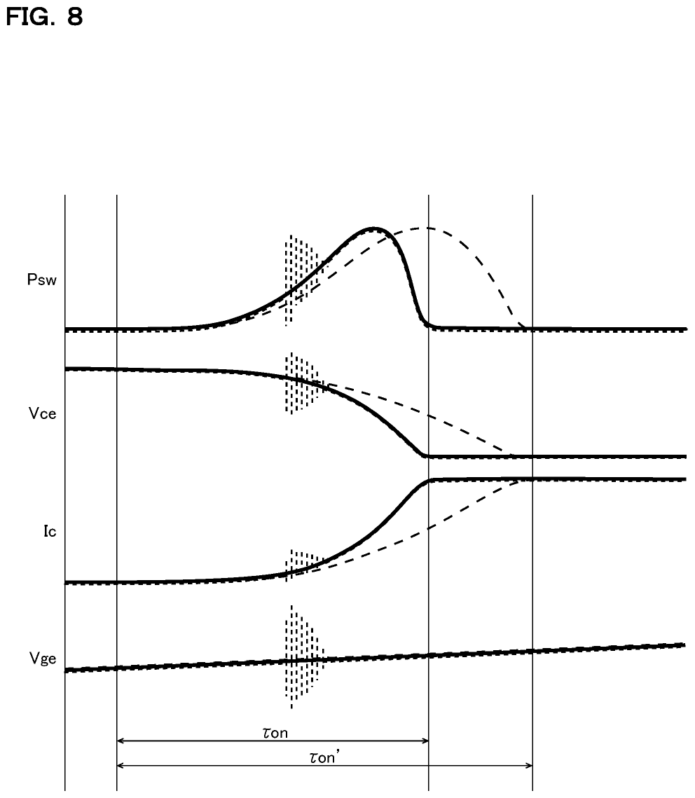

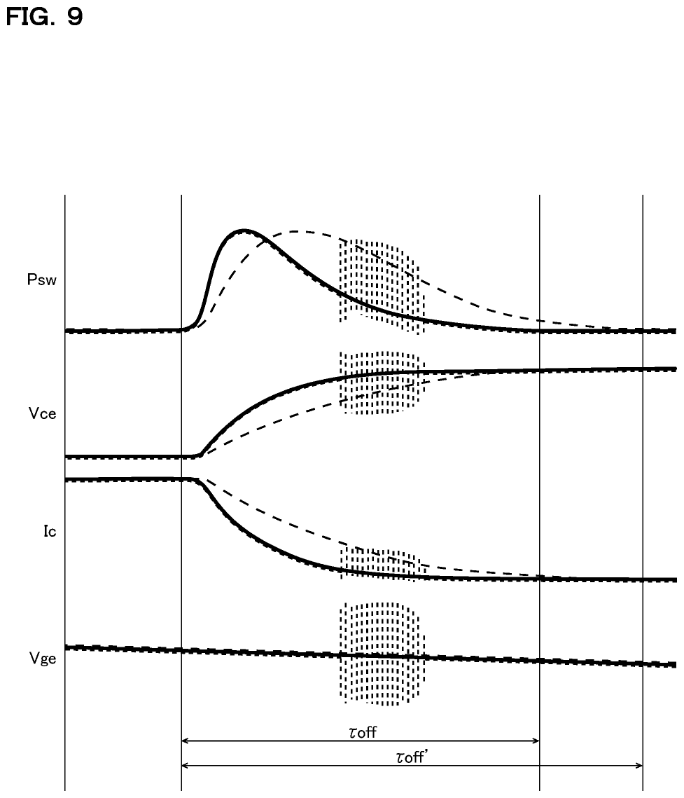

FIGS. 8 and 9 are diagrams showing the turn-on response and the turn-off response, respectively, of the switching element SW of the second embodiment (FIG. 7), illustrating with respect to the switching element SW, from top down, the switching loss Psw, the collector-to-emitter voltage Vce, the collector current Ic, and the gate-to-emitter voltage Vge. The short-stroke broken lines and long-stroke broken lines in the diagrams respectively show the turn-on response and the turn-off response of the switching element SW of the comparative example (FIG. 1) and first embodiment (FIG. 4) described previously.

With the switch driving circuit 1 according to the embodiment, as a result of the dumping resistor Rd being added, it is possible to suppress gate oscillation during low-speed switching while keeping the turning-on transition period τon and the turning-off transition period τoff substantially as long as those of the comparative example (for example, 120 μs). This helps prevent an unnecessary increase in the switching loss Psw; and thus makes the thermal breakdown of the switching element SW less likely.

<A Vehicle>

FIG. 7 is a diagram showing one configuration example of a vehicle. The vehicle X of this configuration example is an electric vehicle without an internal combustion engine (what is called a pure EV (electric vehicle)). The vehicle X includes a heater X10, a driving battery X20, an auxiliary battery X30, and a motor X40.

The heater X10 is a kind of load device that produces heat by being fed with the supply voltage VDD (of, for example, 100 V to 800 V) from the driving battery X20. As the heater X10, for example, the load device 10 (FIG. 4) described previously can be suitably used. In that case, suitably used as the load RL that serves as a heating member is, for example, a PTC (positive temperature coefficient) thermistor with a resistance value that increases as temperature rises, or a nichrome wire with a high resistance value. In this way, the vehicle X, which cannot use the exhaust heat from an internal combustion engine, is provided with the heater X10 as a heat source for heating.

The driving battery X20 is an HV (high voltage) battery that feeds the supply voltage VDD to the heater X10 and the motor X40. Suitably used as the driving battery X20 is, for example, a nickel metal hydride battery or a lithium-ion battery.

The auxiliary battery 30 is a lead storage battery that outputs a voltage of 12 V, that is, the same voltage as in common engine vehicles. The auxiliary battery 30 is used as a power source for various kinds of electric components (such as a car navigation system, a car audio system, an air conditioner, and lamps).

The motor X40 is a driving power source for driving tires (the rear wheels in the diagram) of the vehicle X. The motor X40 operates by being fed with the supply voltage VDD from the driving battery X20. Suitably used as the motor X40 is, for example, a DC motor or an AC motor (for example, a water-cooled synchronous motor).

The vehicle X includes, other than the above-mentioned components X10 to X40, various components (such as an accelerator, a brake, an electric hydraulic brake pump, an ECU (electronic control unit), a CAN (controller area network), an electric power steering system, a transmission, a selector lever, a combination meter, an air conditioner, a charge connector, a vehicle-mounted battery charger, a DC/DC converter, an inverter, and various lamps), although these are omitted from illustration and detailed description.

<Further Modifications>

Although the above description deals with an example of a switch driving circuit for a heater mounted on an electric vehicle, this is not meant to limit the application of the present invention. The present invention can be widely applied to switch driving circuits in general that perform low-speed switching of a switching element.

Likewise, the various technical features disclosed herein may be implemented in any other manner than in the embodiments described above, and allow for many modifications without departing from the spirit of the present invention. That is, the above embodiments should be understood to be in every aspect illustrative and not restrictive. The scope of the present invention is defined not by the description of the embodiments given above but by the appended claims, and should be understood to encompass any modifications made in a sense and scope equivalent to those of the claims.

### INDUSTRIAL APPLICABILITY

The switch driving circuit disclosed herein finds applications as means for driving, for example, a switching element in a heater mounted on an electric vehicle.

### LIST OF REFERENCE SIGNS

1 switch driving circuit
10 load device
20 power supply
BD body diode
Cge, Cgc gate capacitor
L1, L2 conductor inductance
Rd dumping resistor
Rg gate resistor
RL load (resistive load)
SG signal source
SW switching element (IGBT)
X vehicle (pure EV)
X10 heater
X20 driving battery
X30 auxiliary battery
X40 motor

1. A switch driving circuit comprising:
a signal source configured to pulse-drive a gate signal for a switching element connected in series with a load;
a gate resistor connected between the signal source and a gate of the switching element;
a gate capacitor of which a first terminal is connected to the gate of the switching element; and
a dumping resistor connected between a second terminal of the gate capacitor and an emitter or source of the switching element.

2. The switch driving circuit according to claim 1,
wherein a resistance value of the dumping resistor is equal to 1/100 to 1/1000 of a resistance value of the gate resistor.

3. The switch driving circuit according to claim 1,
wherein a turning-on transition period and a turning-off transition period of the switching element are each 80 μs to 1 s.

4. A load device comprising:
a load;
a switching element connected in series with the load; and
the switch driving circuit according to claim 1.

5. The load device according to claim 4, wherein the switching element is an IGBT, or is an SiC-MOSFET or an Si-MOSFET.

6. The load device according to claim 4, wherein the load is a resistive load.

7. A vehicle comprising:
a battery; and
a load device according to claim 4 configured to be fed with electric power from the battery.

8. The vehicle according to claim 7, wherein the load device is a heater.

9. The vehicle according to claim 8 having no internal combustion engine to serve as a heat source.

10. The vehicle according to claim 7, wherein the battery is a driving battery configured to output a voltage of 100 to 800 V.
